(19) United States
(12) Patent Application Publication
(10) Pub. No.: US 2023/0396150 A1
(43) Pub. Date: Dec. 7, 2023

(54) NFET HALF BRIDGE CIRCUIT, AND ARRANGEMENT AND USE RELATED TO NFET HALF BRIDGE CIRCUIT

(71) Applicant: Lumineq Oy, Espoo (FI)

(72) Inventors: Mika SIRKIÄ, Espoo (FI); Pertti SORRI, Espoo (FI)

(21) Appl. No.: 18/033,043

(22) PCT Filed: Oct. 21, 2021
(86) PCT No.: PCT/FI2021/050702

§ 371 Date: Apr. 20, 2023

(30) Foreign Application Priority Data
Oct. 22, 2020 (FI) 20206046

(51) Int. Cl. H02M 1/088; H02M 7/538; H02M 1/00; H03K 17/082; G09G 3/32

(52) U.S. Cl. CPC H02M 1/088; H02M 7/53803; H02M 1/0006; H03K 17/0822; G09G 3/32; H03K 2217/0063; H03K 2217/0072; G09G 2320/0223; G09G 2330/025; G09G 2330/04; G09G 2330/028

(57) ABSTRACT

NFET half bridge circuit with current regulation is disclosed. The NFET half bridge circuit (100) comprises a regulator (140) arranged to determine a limited current (107sh) from the high source node (130s) of the high side NFET (130) and pass the limited current (107sh) to the output node (155), connect the input voltage (106i) of the high side control node (106) to the regulator (140), drop the input voltage (106i) to a regulated voltage (106o) by a voltage drop (106vd), which is directly governed by the limited current (107sh) from the high source node (130s) of the high side NFET (130), and connect the regulated voltage (106o) to the high gate node (130g) of the high side NFET (130). Also arrangement and use related to the NFET half bridge circuit is disclosed.

### FIELD OF THE INVENTION

The present invention relates to an improved current regulation in an NFET half bridge circuit, and more particularly to an NFET half bridge circuit according to a preamble of claim 1. The present invention relates also to an arrangement related to an NFET half bridge circuit and more particularly to an arrangement according to a preamble of claim 7. The present invention relates also to a use related to an NFET half bridge circuit and more particularly to a use according to claim 9.

### BACKGROUND OF THE INVENTION

Field-Effect Transistor (“FET”) of N type (“NFET”) half bridge circuit or NFET half bridge device is a well-known circuit and circuit topology for coupling an alternating voltage to a load. The topology is especially well suited for driving a load with a rectangular pulse waveform that alternates between a high voltage and a zero voltage. Maximum power level of the output is mostly determined by the two NFETs used for the alternating switching of the two voltage levels, V_{BUS1} and V_{BUS2}. The NFET half bridge circuit is widely used e.g. in power converters and motor drives and increasingly in driving display devices like thin film electroluminescent (“TFEL”) displays (“TFEL displays”). In switching applications, the NFETs are typically enhancement type FET devices. In N type FETs, channel of the FET is composed of electrons (negative charges, “N” for negative) as majority current carriers.

Switching devices like discrete FETs are a large part of the cost of the device, and N type FET devices typically have lower “on” resistance (where their channel in a well-conducting state) than P type devices of the same size and cost. Additionally, by using two identical NFET switches in a half-bridge setup, designing timing arrangements and requirements such as nonoverlap and dead time can be simplified. For these reasons, half-bridge configurations typically consist of two N type devices, not one N and one P type device. In general, the electrical behaviour and design methods related to field effect transistors (FETs) are well known in the art.

To keep an NFET device in a conducting state, the gate-source voltage must be maintained positive, typically at the level of e.g. 12V. For this purpose, the NFET half bridge circuit may use e.g. a well-known bootstrap capacitor arrangement where the supply voltage, stored in a bootstrap capacitor, is used to boost the voltage of the gate node of the so-called high side NFET device higher than either one of the DC voltages that are usually at least available, the typically “low” supply voltage V_{CC} and the typically “high” first bus voltage V_{BUS1}. Other approaches can also be used for this purpose, e.g. a DC voltage source.

In the prior art, when the high side NFET is conducting, a short circuit or a load with a low impedance in the output becomes a challenge as there is nothing to stop a destructive current from flowing from the high voltage node through the NFET in an “on” state to the short circuited output node. Similarly, as the operation is based on alternating switching of two NFET devices (for example, one in a conducting state, the other in a non-conducting state), it is important that the two NFET devices are not in the conducting state at the same time as this would generate a short circuit through both of the NFET devices from the (positive) high voltage node to the ground (or negative high voltage node), which would again harm the NFET half bridge circuit. In this regard, synchronization and switching capabilities of the two NFET devices are important.

Thus, there is a need to improve the NFET half bridge circuits and their current regulation capabilities especially for the high-side NFET device and make sure they remain synchronized in their switching operation.

### BRIEF DESCRIPTION OF THE INVENTION

An object of the present invention is to provide an improved circuit (device) for the output current regulation in an NFET half bridge circuit. In particular, the objects of the invention are achieved by a half bridge circuit characterized by what is stated in the independent claim 1. An object of the present invention is also to provide an arrangement related to the improved NFET half bridge circuit. In particular, the objects of the invention are achieved by an arrangement according to claim 7. An object of the present invention is also to provide a use related to the improved NFET half bridge circuit. In particular, the objects of the invention are achieved by a use according to claim 9.

The preferred embodiments of the invention are disclosed in the dependent claims.

The invention is based on the idea of providing a regulator that adjusts the gate voltage of the high side NFET based on the source current of the high side NFET which is also the load current fed to the load during a half cycle.

According to an aspect of the invention, an N type Field-Effect Transistor (“NFET”) half bridge circuit is disclosed. The NFET half bridge circuit comprises a supply voltage node, a first bus voltage node comprising a first bus voltage, a second bus voltage node comprising a second bus voltage, and an output node. The NFET half bridge circuit is arranged to connect the output node to the second bus voltage node for the duration of a first active period of a first half cycle, and to connect the output node to the first bus voltage node for the duration of a second active period of a second half cycle. The NFET half bridge circuit further comprises a high side NFET element comprising a high gate node, a high drain node connected to the first bus voltage node, and a high source node. The NFET half bridge circuit further comprises a low side NFET element comprising a low gate node, a low drain node connected to the output node, and a low source node connected to the second bus voltage node. The NFET half bridge circuit further comprises a control unit comprising a low side control node connected to the low gate node of the low side NFET and arranged to control the low side NFET to a conducting state for the duration of the first active period of the first half cycle, and a high side control node arranged to control the switching of the high side NFET, the high side control node comprising an input voltage for setting the high side NFET in a conducting state for the duration of the second active period of the second half cycle. According to an aspect of the invention, the NFET half bridge circuit comprises a regulator arranged to determine a limited current from the high source node of the high side NFET and pass the limited current to the output node, connect the input voltage of the high side control node to the regulator, drop the input voltage to a regulated voltage by a voltage drop, which is directly governed by the limited current from the high source node of the high side NFET, and connect the regulated voltage to the high gate node of the high side NFET. With this aspect, the danger of a short circuited load destroying the circuit is clearly solved or at least alleviated.

In an embodiment, the regulator of the NFET half bridge circuit comprises a gate voltage input node connected to the high side control node, the gate voltage input node comprising the input voltage, a gate voltage output node connected to the high side NFET high gate node, the gate voltage output node comprising the regulated voltage, a limited current input node connected to the high source node of the high side NFET, and a limited current output node connected to the output node. The regulator is arranged to drop the input voltage to the regulated voltage by the voltage drop, which is directly governed by the current between the limited current input node and the limited current output node of the regulator, and connect the regulated voltage to the gate voltage output node. With this, the danger of a short circuited load destroying the circuit is clearly solved or at least alleviated.

In an embodiment, the regulator of the NFET half bridge circuit comprises a regulating resistor connected between the gate voltage input node and the gate voltage output node, and a current controlled current source comprising a controlling current input node connected to the limited current input node, a controlling current output node connected to the limited current output node, a controlled current input node connected to the gate voltage output node, and a controlled current output node connected to the limited current output node, the current controlled current source being arranged to control the current between the controlled current input node and controlled current output node directly by the current flowing between the controlling current input node and the controlling current output node, current between the controlled current input node and controlled current output node causing the voltage drop over the regulating resistor from the input voltage to the regulated voltage. A current controlled current source is a general circuit concept that can be realized in different ways. With this, the danger of a short circuited load destroying the circuit is clearly solved or at least alleviated.

In an embodiment, the regulator of the NFET half bridge circuit comprises a gate voltage output node connected to the high gate node of the high side NFET to connect the regulated voltage to the high gate node of the high side NFET element, a regulating resistor connected between the gate voltage input node and the gate voltage output node, an NPN type BJT (bipolar junction transistor) comprising a base connected to the limited current input node, an emitter connected to the limited current output node, and a collector connected to the gate voltage output node. A base-emitter resistor is connected between the limited current output node and the limited current input node, the base-emitter resistor arranged to regulate the NPN type BJT collector current based on the base-emitter voltage over the base-emitter resistor, collector current causing the voltage drop over the regulating resistor from the input voltage to the regulated voltage. This circuit gives a practical embodiment for the current controlled current source. With this, the danger of a short circuited load destroying the circuit is clearly solved or at least alleviated.

In an embodiment, the regulator of the NFET half bridge circuit comprises a discharge diode comprising a cathode node and an anode node connected parallel to the regulating resistor, cathode node connected to the gate voltage input node and anode node connected to the gate voltage output node. Discharge diode helps in making turning the high side NFET off faster, increasing the circuit reliability.

In an embodiment, the control unit of the NFET half bridge circuit is a bootstrap control unit, and the NFET half bridge circuit comprises a bootstrap capacitor comprising a bootstrap capacitor first node and a bootstrap capacitor second node, the bootstrap capacitor first node being connected to the supply voltage node and the second node being connected to the output node, bootstrap control unit arranged to set the input voltage to the high side control node for setting the high side NFET in the conducting state for the duration of the second active period of the second half cycle with the voltage stored in the bootstrap capacitor. This is one practical implementation in keeping the high side NFET open for the duration of the second active period.

As another aspect of the present invention, an arrangement for driving a thin film electroluminescent (“TFEL”) display panel is disclosed. The arrangement comprises a display electrode with an N type Field-Effect Transistor (“NFET”) half bridge circuit. The NFET half bridge circuit comprises: a supply voltage node, a first bus voltage node comprising a first bus voltage, a second bus voltage node comprising a second bus voltage, an output node connected to the display electrode of the TFEL display panel for driving the TFEL display panel. The NFET half bridge circuit is arranged to connect the output node to the second bus voltage node for the duration of a first active period of a first half cycle, and connect the output node to the first bus voltage node for the duration of a second active period of a second half cycle. The NFET half bridge circuit further comprises a high side NFET element comprising a high gate node, a high drain node connected to the first bus voltage node, and a high source node, a low side NFET element comprising a low gate node, a low drain node connected to the output node and a low source node connected to the second bus voltage node. The NFET half bridge circuit comprises a control unit comprising a low side control node connected to the low gate node of the low side NFET and arranged to control the low side NFET to a conducting state for the duration of the first active period of the first half cycle, and a high side control node arranged to control the switching of the high side NFET, the high side control node comprising an input voltage for setting the high side NFET in a conducting state for the duration of the second active period of the second half cycle. The NFET half bridge circuit further comprises a regulator arranged to determine a limited current from the high source node of the high side NFET and pass the limited current to the output node, connect the input voltage of the high side control node to the regulator, drop the input voltage to a regulated voltage by a voltage drop, which is directly governed by the limited current from the high source node of the high side NFET, and connect the regulated voltage to the high gate node of the high side NFET. With this, the danger of a short circuited load destroying the circuit is clearly solved or at least alleviated.

In an embodiment, an arrangement related to an NFET half bridge circuit is disclosed, the NFET half bridge circuit defined as above. With this, the danger of a short circuited load destroying the circuit is clearly solved or at least alleviated.

As yet another aspect of the present invention, a use of an NFET half bridge circuit as defined above for driving a display electrode of a TFEL display panel is disclosed. With this, the danger of a short circuited load destroying the circuit is clearly solved or at least alleviated.

In short, with the present invention, the prior art problem of a short-circuited load and the risk of a failed synchronization hampering the NFET half bridge circuit is solved or at least alleviated.

### BRIEF DESCRIPTION OF THE DRAWINGS

The invention is described in detail by means of specific embodiments with reference to the enclosed drawings, in which

FIG. 1a is prior art schematic representation of a general half bridge circuit,

FIG. 1b defines the standard nodes of an N type field effect transistor (NFET), for example an N type MOSFET,

FIG. 1c defines the standard nodes (base, emitter, collector) of an NPN type bipolar junction transistor (BJT),

FIGS. 2a and 2b illustrate the operation of a prior art NFET half bridge circuit,

FIG. 3a shows an embodiment according to an aspect of the present invention,

FIG. 3b shows another embodiment according to an aspect of the present invention,

FIG. 4 illustrates the concept of a voltage drop being monotonically increasing function of the limited current,

FIG. 5 shows another embodiment according to an aspect of the invention,

FIG. 6 shows another embodiment according to an aspect of the invention, and

FIG. 7 shows yet another embodiment according to another aspect of the invention.

### DETAILED DESCRIPTION OF THE INVENTION

In the following description, like numbers (e.g. 20) or labels (e.g. 21a) denote like elements. The following definitions also apply:

In the present application, “biasing” means setting of the DC (direct current) operating conditions (current and voltage) or operating point of active devices in a circuit.

In the present application, an “NFET” or an “NFET element” both mean an N type, enhancement type field effect transistor semiconductor element. When the element is arranged with bias voltages in its nodes, the element acts as a switch between its drain node and source node. Switching to an open state and switching to a closed state is controlled with a voltage applied to the gate node of the element. Also an insulated gate bipolar transistor (IGBT) is an NFET in the present application as the switching is controlled by a field effect and gate voltage. For IGBTs, collector node is the drain node, and emitter node is the source node.

In the present application, an NFET in an “open” state means that the NFET (between its drain and source nodes) is in a “non-conducting” or “high-impedance” state, or in an “off” state, analogous to an open switch. This is not to be confused with the state of the channel of the NFET which is void of charge carrying capacity, and thus the channel is closed.

In the present application, an NFET in an “closed” state means that the NFET (between its drain and source nodes) is in a “conducting” or “low-impedance” state, or in an “on” state, again analogous to a closed switch. This is not to be confused with the state of the channel of the NFET which in this state has significant charge carrying capacity, and thus the channel is open.

In the present application, “for the duration of” a period means that something takes place for the entire duration of said period.

In the present application, “during” a period of time (e.g. cycle spanning a period time) means that something happens during the period, but not necessarily for the entire duration of the period.

In the present application, “connected”, “connect” or “connection” means, unless otherwise specified, that two circuit elements or their nodes are connected functionally, galvanically or electrically, possibly with one or more other circuit elements, together, to establish a section of an electric circuit.

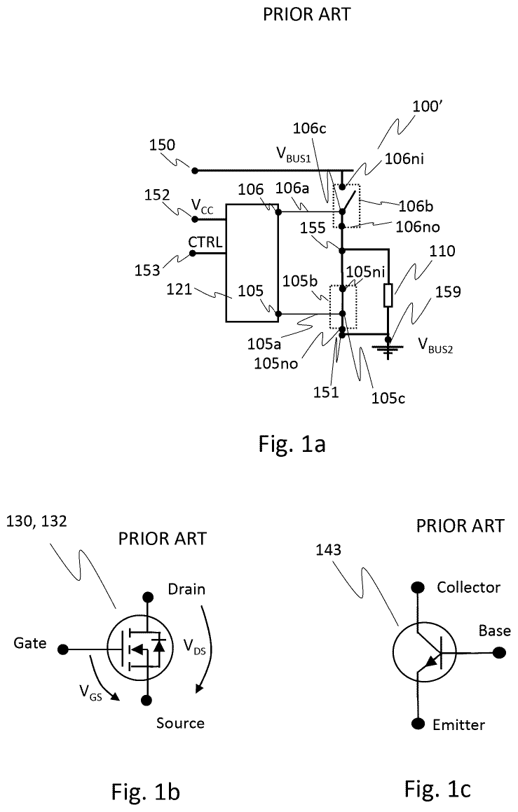

FIG. 1a shows a basic prior art half bridge electrical circuit 100′ which is used to drive a load 110. Load may be a resistive or reactive, or time dependent (that is, its impedance (having resistive real part and reactive imaginary part) depends on a point of time) or frequency dependent (that is, its impedance depends on the frequency) or any combination thereof. Circuit 100′ comprises a control unit 121 that controls the alternated switching of the switches, the high side switch 106b and the low side switch 105b through a high side control node 106 and a low side control node 105, respectively. The concept of “high” and “low” stems from the location of the switch in the circuit. As shown in FIG. 1a, switch 106b is connected to the first bus voltage node 150, and switch 105b to the second bus voltage node 151, which is, in this case, connected to a ground node 159. Connection between the control unit 121 and the high side switch 106b is arranged with a high side control connection 106a which can comprise e.g. an electric conductor, wire, cable, printed circuit board copper trace or other functional connection carrying the signal to command the switch 106b from the high side control node 106, said functional connection possibly comprising other circuit elements. Similarly, connection between the control unit 121 and low side switch 105b is arranged with a high side control connection 105a which can comprise e.g. an electric conductor, wire, cable, printed circuit board copper trace or other functional connection carrying the signal to command the switch 105b from the low side control node 105, said functional connection possibly comprising other circuit elements.

Switches 106b and 105b can comprise electrical circuits or components arranged to perform a switching function (enter a low-impedance or high impedance state) when a control voltage or control current is applied to the control nodes 106c and 105c of the high side switch 106b and low side switch 105b, respectively. In a low-impedance state (also called “closed” or “on” state), the connection between the switching nodes 106ni and 106no is ideally short-circuited or is arranged to have a low impedance or low resistance. In a high-impedance state (also called “open” state or “off” state), the connection between the switching nodes, input switching node 106ni and output switching node 106no, is ideally open-circuited, or is arranged to have a high impedance or a high resistance. The same applies for switch 105b and its switching nodes, input switching node 105ni and output switching node 105no. In FIG. 1, switch 106b is shown to be in an open state and switch 105b in a closed state.

Switches 105b and 106b can each comprise one or more field effect transistors (FET) or one or more bipolar junction transistors (BJT) that, when arranged with biasing voltages and supporting circuits, can be arranged to perform switching functions according to basic electrical engineering principles.

When switches 105b and 106b are arranged to a closed state and to an open state in an alternated manner (when switch 105b is open, switch 106b is closed and vice versa), the circuit 100′ can connect the load 110 to either first bus voltage V_{BUS1} provided with first bus voltage node 150, or a second bus voltage V_{BUS2}, provided for example with a ground node 159. In general, for a proper operation, V_{BUS2} voltage must be lower than V_{BUS1} voltage. For controlling the operation, the control unit 121 is supplied with a supply voltage 152 (V_{CC}), and to e.g. trigger the switching of the switches 105b and 106b, the control unit 121 is arranged with a control node 153 to arrange control unit 121 to receive commands from other electrical system units. Control unit 121 can e.g. receive information of a switching frequency command through an interface arranged in the control node 153, and based on this information, supply alternating switching signals to switches 105b and 106b based on the switching frequency indicated in the said command.

Switches 105b and 106b may be in an open state simultaneously as this leaves the load 110 in a floating state which may be even desirable. In other words, the switching on of the second switch (105b or 106b) does not have to follow immediately the switching off of the first switch (106b or 105b). However, it is clear that switches 105b and 106b in the circuit of FIG. la cannot be in the closed state (conducting state or “on” state) at the same time, as the circuit would short circuit the first bus voltage node 150 and second bus voltage node 151 with only a small or no impedance in between, resulting in almost an assured destruction of the circuit 100′. Load 110 may be e.g. an electric motor or a display electrode of a TFEL (thin film electroluminescent) display or any other device that needs to be driven with an alternating pulsed driving voltage to operate.

FIG. 1b shows the common conventions in naming the nodes of an enhancement N type FET (field effect transistor), device show and deployed later in the figures and related embodiments as units 130 and 132. This device is an example of a circuit device called NFET in the present application. For the purposes of the present application and subject to correct bias conditions for the NFET and its nodes (gate, source, drain), the NFET of enhancement type operates as a switch where a positive voltage to the gate node, relative to the source node, V_{GS} opens the channel between the drain and the source node. Thus, the NFET may be arranged to operate as a switch with gate as the control node (e.g. 105c or 106c) and drain and source as the switching nodes (more specifically input switching nodes 105ni and 106ni and output switching nodes 105no and 106no, respectively).

FIG. 1c shows another important, well-known prior art semiconductor circuit element and the common conventions therein. FIG. 1c depicts an NPN type BJT (bipolar junction transistor comprising a P type base surrounded with N type emitter and collector), called a “BJT” or an “NPN type BJT” in the present application. Arranging appropriate bias voltages to the circuit nodes, the BJT acts as a current controlled current source. In particular, when the base-emitter voltage Vim exceeds a threshold voltage, e.g. 0.7V, and the voltage between the collector-emitter junction is positive, BJT acts as a current controlled current source so that collector current I_{C} (current into the collector) is some orders of magnitude higher than the base current I_{B} (current into the base), I_{C}=βI_{B}. Value for β may be e.g. 100. Naturally, emitter current IE is the sum of the base and collector currents flowing into the BJT, I_{E}=I_{C}+I_{B}. However, in this equation, the contribution of is I_{B} relatively insignificant to the emitter current I_{E}.

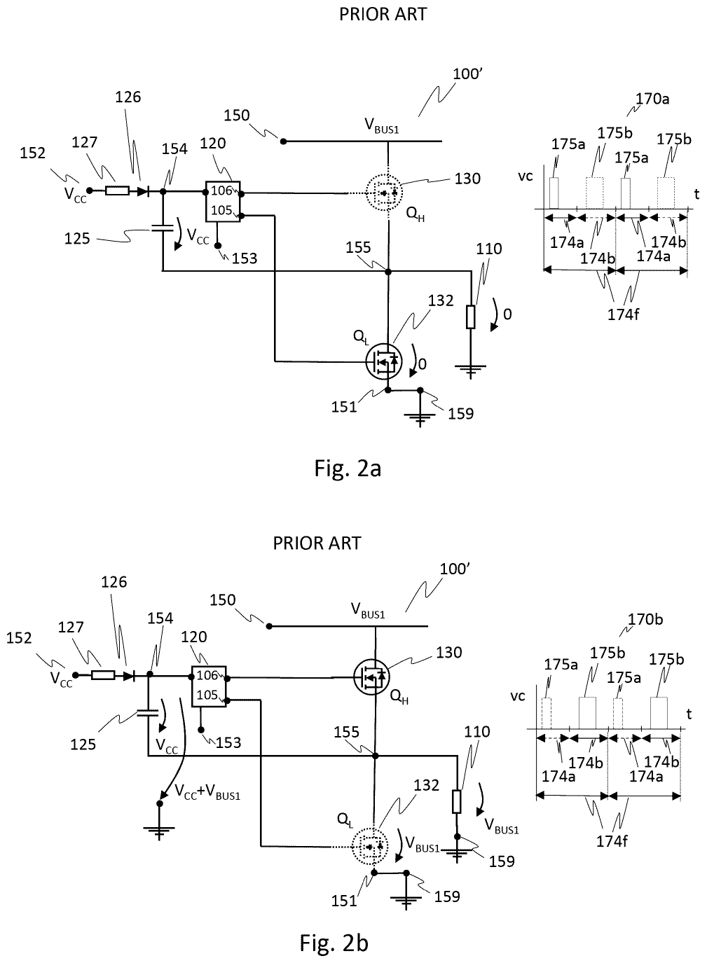

FIGS. 2a and 2b illustrate a prior art NFET half bridge circuit 100′ and an arrangement for keeping the high side NFET in a conducting state for the duration of an active period of a half cycle. In FIGS. 2a and 2b, a so-called bootstrap capacitor 125 is shown. As discussed in FIG. 1a, NFET half bridge circuit operates in two half cycles, first half cycle 174a and second half cycle 174b, shown in more detail in timing diagrams 170a and 170b. As shown, a full cycle 174f comprises the first half cycle 174a and the second half cycle 174b. In each of the first half cycles, the low side NFET element 132 is in a closed state (conducting state) at least during a portion of the first half cycle, more specifically for the duration of the first active period 175a of the first half cycle 174a, and the high side NFET 132 element is in an open (non-conducting) state during the entire first half cycle 174a.

FIG. 2a shows a state of the circuit when, arranged by a bootstrap control unit 120, the low side NFET 132 (also marked as Q_{L}) is closed (“on”) and the high side NFET 130 (marked also as Q_{H}) is open (“off”), indicated with a dotted symbol. This is the operation during the first half cycle 174a. First half cycle 174a, the duration of which is shown with a solid arrow 174a, comprises a first active period 175a, shown with a solid line in timing diagram 170a. Second half cycle 174b is show with a dashed arrow, and the second half cycle 174b comprises a second active period 175b, shown with a dashed line in timing diagram 170a. During the first half cycle 174a, the load 110 is connected to the second bus voltage node 151, V_{BUS2}, in this case a ground voltage or zero voltage, through the output node 155 for the duration of the first active period 175a of the first half cycle 174a.

During the first half cycle, a bootstrap capacitor 125 is charged through the supply voltage node 154 to a voltage V_{CC}. It is customary that the circuit comprising a bootstrap capacitor 125 may also comprise a rectifying supply voltage diode 126 and a current limiting resistor 127 to arrange the charging of the bootstrap capacitor 125. For the duration of the first active period 175a, voltage over the load 110 is the voltage of the second bus voltage node 151, V_{BUS2}, as the NFET 132 is in the “on” state, in this case the ground voltage 0V for the duration of the first active period 175a.

Timing diagram 170a illustrates further the concept of the first active periods 175a and second active periods 175b. In the normal operation of the device 100′, there are naturally one or more first half cycles 174a and one or more second half cycles 174b.

FIG. 2b shows the operation of the NFET half bridge circuit during the second half cycle 174b. Again arranged by the bootstrap control unit 120, the low side NFET 132 is open (indicated with a dotted symbol) and, at least during some of the second half cycle, for the duration of the second active period 175b of the second half cycle 174b, the high side NFET 130 is in a conducting state. Thus, the load 110 is connected to the first bus voltage node 150, in this case high voltage V_{BUS1} by the output node 155, through the high side NFET 130. When the voltage over the load 110 (which in FIG. 2b is also the voltage of the output node 155) rises towards the high voltage, the high side NFET would, without anything to the contrary, switch back to “off” state (non-conducting state) as the gate-source voltage would start to drop below the voltage required to keep the NFET in the “on” state. The bootstrap control unit 120 may be arranged to connect the voltage in store in the bootstrap capacitor 125, V_{CC}, in series with the voltage of the output node 155 during the active period 175b of the second half cycle 174b. Thus, the gate-source voltage V_{GS} is kept at a voltage that sets the high side NFET 130 in a conducting state during the second active period 175b of the second half cycle 174b.

Stated in more general terms, the bootstrap control unit 120 is arranged to set the high side NFET 130 in a conducting state for the duration of the second active period 175b of the second half cycle 174b. In timing diagram 170b, timing of the second half cycles 174b each comprising second active periods 175b is shown schematically with a solid line, and the first half cycles 174a and first active periods 175a are shown with dashed arrows and lines, respectively.

In the present application, the concept of a “half cycle” is an established name for an alternating operation of a circuit device, and therefore two subsequent half cycles can comprise two time periods of different length, e.g. in time 60% and 40% of the time of one full cycle 174f, or alternatively exactly two halves, 50% and 50% of the time of the one full cycle 174f. Further, the first active period 175a of the first half cycle 174a, as shown in timing diagrams 170a and 170b, does not have to last for the entire half cycle 174a. Outside the periods of the first active period 175a and second active period 175b, the circuit 100′ is arranged e.g. to set the load 110 in a floating (high-impedance) state where the load 110 is not connected to the first bus voltage node 150 or to the second bus voltage node 151. This can be arranged by setting both the high side NFET 130 and the low side NFET 132 to an open or high-impedance state.

A circuit comprising a bootstrap capacitor is just one example of an arrangement in a device to set the high side NFET 130 in a conducting state for the duration of the second active period 175b of the second half cycle 174b. As one alternative for a bootstrap capacitor, the arrangement in a device may comprise e.g. a DC voltage source.

As shown in timing diagrams 170a and 170b, after the second half cycle 174b, the operation of the NFET half bridge circuit 100′ returns to the first half cycle 174a. The two half cycles 174a and 174b are repeated in an alternated fashion as long as the load 110 is to be driven.

As illustrated in FIGS. 2a and 2b, the concepts of the first half cycle 174a and the second half cycle 174b, the first active period 175a, the second active period 175b and the full cycle 174f are used throughout the present application and have the same meaning.

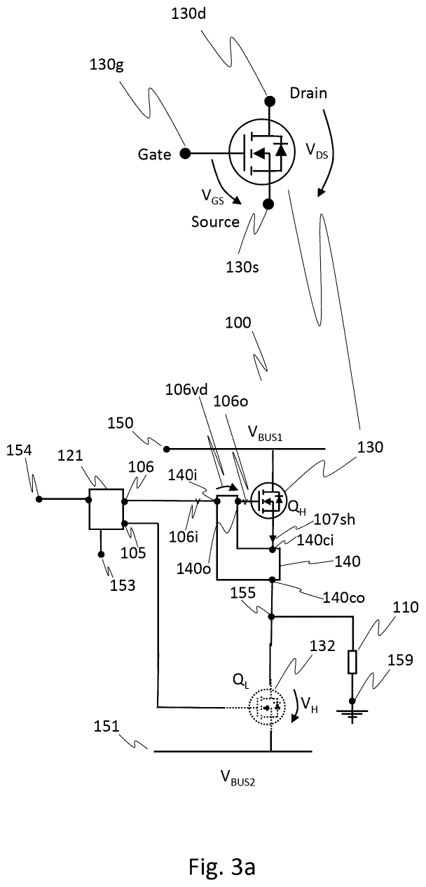

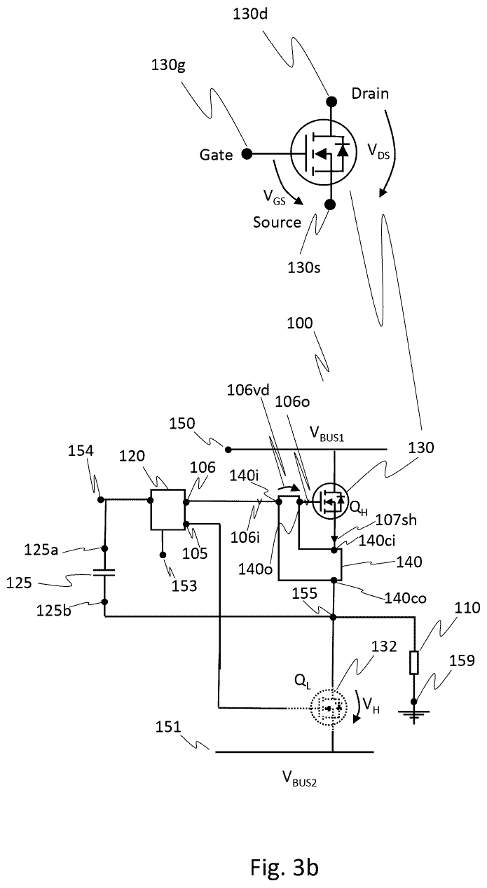

FIG. 3a shows a circuit according to an embodiment of an aspect of the present invention. In FIG. 3a, an NFET half bridge circuit 100 is shown. The NFET half bridge circuit 100 comprises a supply voltage node 154, a first bus voltage node 150 comprising a first bus voltage, a second bus voltage node 151 comprising a second bus voltage and an output node 155. The supply voltage node 154 is arranged with a supply voltage V_{CC}, typically a DC voltage, e.g. 12V.

The NFET half bridge circuit 100 is arranged to connect the output node 155 to the second bus voltage node 151 for the duration of a first active period 175a of a first half cycle 174a. The NFET half bridge circuit 100 is also arranged to connect the output node 155 to the first bus voltage node 150 for the duration of a second active period 175b of a second half cycle 174b. The NFET half bridge circuit 100 may be arranged to connect the output node 155 to the second bus voltage node 151 for the duration of the first active period 175a of a first half cycle 174a with a low-impedance connection. The NFET half bridge circuit 100 may also be arranged to connect the output node 155 to the first bus voltage node 150 for the duration of the second active period 175b of a second half cycle 174b with a low-impedance connection.

The first bus voltage node 150 is arranged with a first bus voltage V_{BUS1} that is to be used for driving the load during the second half cycle 174b, for the duration of the second active period 175b. The V_{BUS1} voltage may be e.g. 100V or 1000V, but if the load 110 so requires, the voltage can be also arranged to a lower level. V_{BUS1} may be e.g. 10V. The first bus voltage and the second bus voltage may be e.g. essentially DC voltages or DC voltages with ripple voltages, or AC voltages with DC offset voltages. Important to the invention is that the voltage V_{BUS1} of the first bus voltage node 150 is always higher than the voltage V_{BUS2} of the second bus voltage node 151. In FIG. 3a, the second bus voltage may be the ground voltage, 0V, supplied with the second bus voltage node 151 connected to ground node 159. In general, the second bus voltage node 151 is arranged with a second bus voltage V_{BUS2} that is to be used for driving the load during the first half cycle 174a, for the duration of the first active period 175a.

In an aspect of the current invention, the NFET half bridge circuit 100 comprises further a high side NFET element 130. NFET element 130 comprises the usual nodes of a FET: A high gate node 130g, a high drain node 130d, which is connected to the first bus voltage node 150, and a high source node 130s, as shown in a more detailed illustration of the NFET in FIG. 3a. The concept “high” indicates that the nodes are part of the high side NFET 130, its gate, drain and source, respectively.

Similarly, the NFET half bridge circuit 100 comprises a low side NFET 132 comprising a low gate node 132g, a low drain node 132d connected to the output node 155 and a low source node 132s connected to the second bus voltage node 151. The concept “low” indicates that the nodes are part of the low side NFET 132, its gate, drain and source, respectively. The second bus voltage node 151 comprises a voltage which, less the resistive losses of the circuit, may be arranged to the load during the first active period 175a of the first half cycle 174a.

The NFET half bridge circuit 100 comprises a control unit 121, comprising two control nodes: a low side control node 105 connected to the low gate node 132g of the low side NFET 132 and arranged to control the low side NFET 132 to a conducting state for the duration of the first active period 175a of the first half cycle 174a, and a high side control node 106 arranged to control the switching of the high side NFET 130, the high side control node 106 comprising an input voltage 106i for setting the high side NFET 130 in a conducting state for the duration of the second active period 175b of the second half cycle 174b. However, as will be discussed in more detail, according to the current invention, the input voltage 106i is not directly connected to the high side gate 130g of the high side NFET 130.

The NFET half bridge circuit 100 may also comprise a control node 153 arranged to the control unit 121 for receiving commands from other electrical system units. Control unit 121 can e.g. receive information of a switching frequency command through an interface arranged in the control node 153. Alternatively, the control node 153 may be arranged to receive triggering signals for performing the changes between a first half cycle 174a and a second half cycle 174b.

As discussed already above, the first active period 175a of the first half cycle 174a is the period of time the control unit 121 is arranged generate a voltage to the low side control node 105 to set the low side NFET 132 to a conducting state (“on” state). Similarly, the second active period 175b of the second half cycle 174b is the period of time the control unit 121 is arranged generate a voltage to the high side control node 106 for setting set the high side NFET 130 to a conducting state (“on” state).

According to an aspect of the current invention, the NFET half bridge circuit 100 comprises a regulator 140 arranged to determine a limited current 107sh from the high source node 130s of the high side NFET 130 and pass the limited current 107sh to the output node 155. Determining current or measuring current is a well-known in the electronics art. Current determination can be arranged e.g. with shunt resistors, Hall effect sensors, and magneto-resistive current sensors.

The regulator 140 is also arranged to connect the input voltage 106i of the high side control node 106 to the regulator 140 as the input voltage 106i of the regulator 140.

Further, the regulator 140 is arranged to drop the input voltage 106i (=V₁) to a regulated voltage 106o (=V_{R}) by a voltage drop 106vd (=ΔV), which is directly governed by the limited current 107sh from the high source node 130s of the high side NFET 130 (V_{R}=V₁−ΔV). In the present application, “directly governed” means that the voltage drop 106vd increases or stays the same when the limited current 107sh increases, and that the voltage drop 106vd decreases or stays the same when the limited current 107sh decreases. In other words, directly governed means that the voltage drop 106vd is monotonically increasing function of the limited current 107sh.

The regulator 140 is also arranged to connect the regulated voltage 106o to the high gate node 130g of the high side NFET 130.

If the output node 155 is short circuited and when the NFET half bridge circuit is arranged with a regulator 140 as defined above, the limited current 107sh rises close to a certain maximum value I_{OUTMAX}, but then regulator 140 decreases the gate voltage of the high side NFET 130 through the high gate node 130g as the voltage drop 106vd is directly governed by the limited current 107sh. When the voltage drop 106vd increases, the voltage of the high gate node 130g decreases. In other words, by using the notation above, V_{R}=V₁−ΔV. This makes the channel of the high side NFET 130 between the high drain node 130d and high source node 130s somewhat less conducting in the conducting state of the high side NFET 130. This limits the value of the limited current 107sh to a maximum value I_{OUTMAX}. Thus, current regulation or current limitation is achieved.

In an embodiment and still referring to FIG. 3a, the regulator 140 of the NFET half bridge circuit 100 comprises: a gate voltage input node 140i connected to the high side control node 106, the gate voltage input node 140i comprising the input voltage 106i. The regulator 140 also comprises a gate voltage output node 140o connected to the high gate node 130g of the high side NFET 130 (more detailed illustration of the NFET device is shown with the node names in FIG. 3a for clarity), the gate voltage output node 140o comprising the regulated voltage 106o. The regulator also comprises a limited current input node 140ci connected to the high source node 130s of the high side NFET 130. The regulator 140 also comprises a limited current output node 140co connected to the output node 155. The regulator 140 is arranged to drop the input voltage 106i to the regulated voltage 106o by the voltage drop 106vd. The voltage drop 106vd is directly governed by the limited current 107sh between the limited current input node 140ci and the limited current output node 140co of the regulator 140. The regulator 140 is also arranged to connect the regulated voltage 106o to the gate voltage output node 140o. Again, “directly governed” means that the voltage drop 106vd increases or stays the same when the limited current 107sh increases, and that the voltage drop 106vd decreases or stays the same when the limited current 107sh decreases. In other words, directly governed means that the voltage drop 106vd is monotonically increasing function of the limited current 107sh, and the regulator 140 is arranged to control the voltage drop 106vd between the gate voltage input node 140i and the gate voltage output node 140o so that the voltage drop 106vd is a monotonically increasing function of the limited current 107sh.

FIG. 3b shows another embodiment of the current invention. Following the reasoning of FIGS. 2a and 2b, the NFET half bridge circuit 100 comprises also a bootstrap capacitor 125 comprising a bootstrap capacitor first node 125a and a bootstrap capacitor second node 125b. The bootstrap capacitor first node 125a is connected to the supply voltage node 154 and the second node 125b is connected to the output node 155, as indicated in FIG. 3b. The NFET half bridge circuit 100 comprises a control unit (shown as unit 121 in the present application) which is a bootstrap control unit 120, comprising two control nodes: a low side control node 105 connected to the low side NFET 132 low gate node 132g and arranged to control the low side NFET 132 to a conducting state for the duration of the first active period 175a of the first half cycle 174a, and a high side control node 106 arranged to control the switching of the high side NFET 130, the high side control node 106 comprising an input voltage 106i for setting the high side NFET 130 in a conducting state for the duration of the second active period 175b of the second half cycle 174b. For keeping the high side NFET 130 in a conducting state for the duration of the second active period 175b of the second half cycle 174b, the bootstrap control unit 120 is arranged to couple the voltage in the bootstrap capacitor 125 in series to the voltage of the output node 155. The high side NFET 130 is kept in a conducting state with the voltage supplied by the high side control node 106. This is particularly important when the voltage of the load 110 increases close to that of the voltage of the first bus voltage node 150, as discussed above in relation to FIGS. 2a and 2b. Thus, bootstrap control unit 120 is a version of a control unit 121. Bootstrap control unit 120 is arranged to be connected to a bootstrap capacitor 125 and with the voltage stored in the bootstrap capacitor 125, bootstrap control unit 120 is arranged to set an input voltage 106i to the high side control node 106 for setting the high side NFET 130 in a conducting state for the duration of the second active period 175b of the second half cycle 174b. Charging of the bootstrap capacitor 125 occurs during the first half cycle 174a.

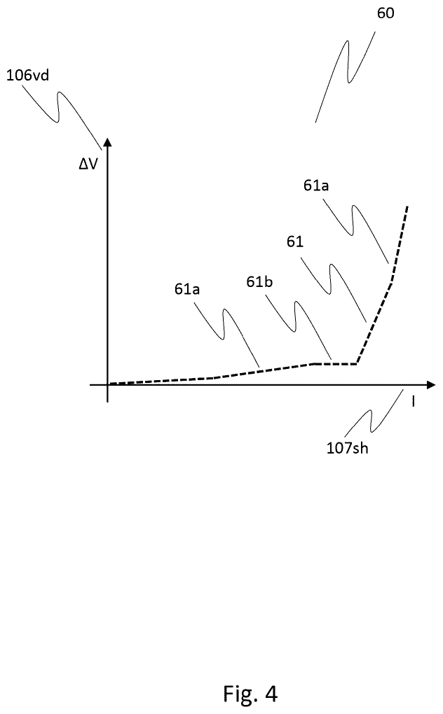

For clarity, FIG. 4 illustrates, in graph 60, the concept of the voltage drop 106vd being a monotonically increasing function of the limited current 107sh. Monotonically increasing function of the voltage drop increases (e.g. in points denoted with label 61a) or stays the same (e.g. point denoted with label 61b). However, a monotonically increasing function does not have, at any point of the function, a decreasing portion which would be indicated as downward sloping segment in graph 60.

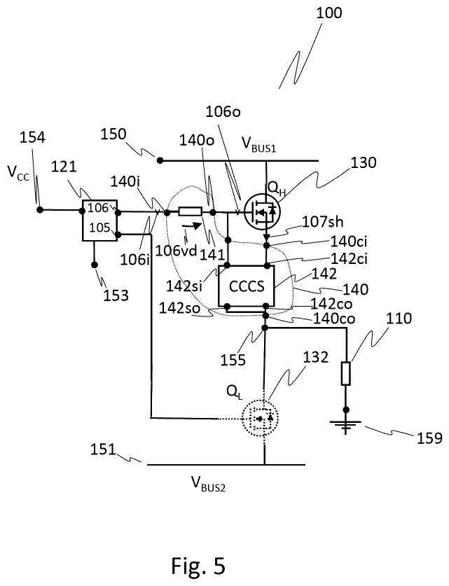

Turning to FIG. 5, another embodiment of an NFET half bridge circuit 100 according to an aspect of the invention is shown. In the embodiment, the regulator 140 comprises a regulating resistor 141 connected between the gate voltage input node 140i and the gate voltage output node 140o. The regulator 140 further comprises a current controlled current source (“CCCS”) 142. A CCCS may be arranged with various circuit elements, e.g. by a connection of an NPN type BJT and a shunt resistor, or by circuit of an operational amplifier and peripheral resistors, as well known to persons skilled in the art.

The current controlled current source 142 comprises a controlling current input node 142ci connected to the limited current input node 140ci, a controlling current output node 142co connected to the limited current output node 140co, a controlled current input node 142si connected to the gate voltage output node 140o, and a controlled current output node 142so connected to the limited current output node 140co. The current controlled current source 142 is arranged to directly govern the current between the controlled current input node 142si and controlled current output node 142so by the current flowing between the controlling current input node 142ci and the controlling current output node 142co. As can be seen in FIG. 5, and by considering that the gate of an NFET is essentially a capacitor, no or only an insignificant current flows into the high side gate node 130g. Thus, the current flowing between the controlled current input node 142si and controlled current output node 142so causes the voltage drop 106vd over the regulating resistor 141 from the input voltage 106i to the regulated voltage 106o. Thus, in more general terms, the regulator 140 is arranged to drop the input voltage 106i to a regulated voltage 106o by the voltage drop 106vd, which is directly governed by the limited current 107sh from the high source node 130s of the high side NFET element 130.

Also related to the embodiment of FIG. 5, in another embodiment, the NFET half bridge circuit 100 may comprise also a bootstrap capacitor 125 comprising a bootstrap capacitor first node 125a and a bootstrap capacitor second node 125b. The bootstrap capacitor first node 125a may be connected to the supply voltage node 154 and the second node 125b may be connected to the output node 155, as indicated in FIG. 3b. In this embodiment, the control unit 121 of the NFET half bridge circuit 100 may be a bootstrap control unit 120, comprising two control nodes: a low side control node 105 connected to the low side NFET 132 low gate node 132g and arranged to control the low side NFET 132 to a conducting state for the duration of the first active period 175a of the first half cycle 174a, and a high side control node 106 arranged to control the switching of the high side NFET 130, the high side control node 106 comprising an input voltage 106i for setting the high side NFET 130 in a conducting state for the duration of the second active period 175b of the second half cycle 174b. For keeping the high side NFET 130 in a conducting state for the duration of the second active period 175b of the second half cycle 174b, the bootstrap control unit 120 is arranged to couple the voltage in the bootstrap capacitor 125 in series to the voltage of the output node 155. The high side NFET 130 is kept in a conducting state with the voltage supplied by the high side control node 106. Thus, bootstrap control unit 120 is a version of a control unit 121. Bootstrap control unit 120 is arranged to be connected to a bootstrap capacitor 125 and with the voltage stored in the bootstrap capacitor 125, bootstrap control unit 120 is arranged to set an input voltage 106i to the high side control node 106 for setting the high side NFET 130 in a conducting state for the duration of the second active period 175b of the second half cycle 174b. Charging of the bootstrap capacitor 125 occurs during the first half cycle 174a. Bootstrap capacitor 125 and bootstrap control unit 120 are not shown in FIG. 5, however.

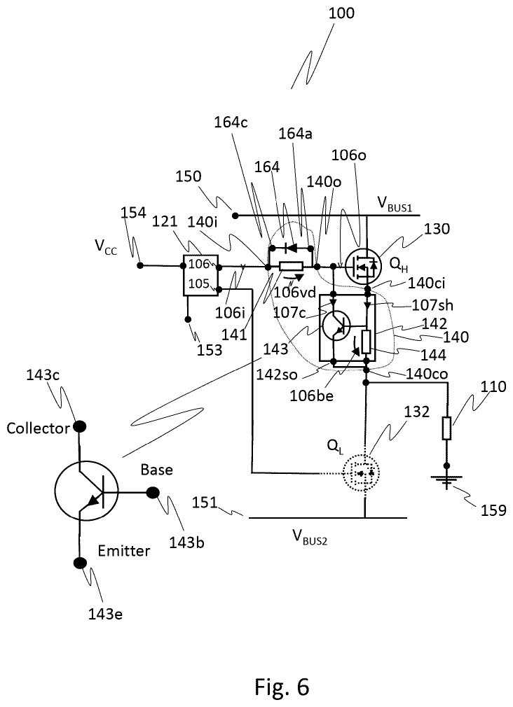

As shown in FIG. 6, in yet another embodiment, a regulator 140 of the NFET half bridge circuit 100 comprises a gate voltage output node 140o connected to the high gate node 130g of the high side NFET 130 to connect the regulated voltage 106o to the high gate node 130g of the high side NFET 130. The regulator comprises further a regulating resistor 141 connected between the gate voltage input node 140i and the gate voltage output node 140o. The regulator also comprises an NPN type BJT 143, which comprises a base 143b connected to the limited current input node 140ci, an emitter 143e connected to the limited current output node 140co, and a collector 143c connected to the gate voltage output node 140o. The regulator comprises also a base-emitter resistor 144 connected between the limited current output node 140co and the limited current input node 140ci. The base-emitter resistor 144 is arranged to regulate the NPN type BJT 143 collector current 107c based on the base-emitter voltage 106be over the base-emitter resistor 144. Said collector current 107c causes the voltage drop 106vd over the regulating resistor 141 from the input voltage 106i to the regulated voltage 106o. In the circuit of FIG. 6, when the base-emitter voltage V_{BE}, which is also the voltage over the base-emitter resistor 144, exceeds a threshold voltage, e.g. 0.7V, the BJT 143 becomes conducting and lets current flow through the regulating resistor 141, causing the voltage drop 106vd over the regulating resistor 141. Stated generally, as can be seen in FIG. 6, again the regulator 140 is arranged to drop the input voltage 106i to the regulated voltage 106o by the voltage drop 106vd, which is directly governed by the limited current 107sh from the high source node 130s of the high side NFET 130 element.

Referring still to FIG. 6, in an embodiment, the regulator 140 comprises a discharge diode 164 comprising a cathode node 164c and anode node 164a connected parallel to the regulating resistor 141, a cathode node 164c connected to the gate voltage input node 140i and an anode node 164a connected to the gate voltage output node 140o. The discharge diode 164 is arranged to provide a faster discharge route for the capacitor of the high side NFET 130 gate region when the second half cycle 174b and the second active period 175b is coming to an end, and the high side NFET 130 is to be set to the non-conducting (or off) state to again enable the closing of the low side NFET 132, that is, set the low side NFET 132 to an “on” or conducting state. Setting the NFET 130 to the “off” state requires that the gate area of the NFET 130 is emptied at least partially of charges keeping the channel of the NFET 130 conducting (and the NFET in a conducting state). Without the discharge diode 164, the synchronization of the alternating switching of the high and low sides can be hampered, and even with the current limiting functionality described in the present application, circuit performance of the NFET half bridge circuit 100 is not optimal if the synchronization and timing of the alternated switching is not able to perform well.

Also related to the embodiment of FIG. 6, in another embodiment, the NFET half bridge circuit 100 may comprise also a bootstrap capacitor 125 comprising a bootstrap capacitor first node 125a and a bootstrap capacitor second node 125b. The bootstrap capacitor first node 125a may be connected to the supply voltage node 154 and the second node 125b may be connected to the output node 155, as indicated in FIG. 3b. In this embodiment, the control unit 121 of the NFET half bridge circuit 100 may be a bootstrap control unit 120, comprising two control nodes: a low side control node 105 connected to the low side NFET 132 low gate node 132g and arranged to control the low side NFET 132 to a conducting state for the duration of the first active period 175a of the first half cycle 174a, and a high side control node 106 arranged to control the switching of the high side NFET 130, the high side control node 106 comprising an input voltage 106i for setting the high side NFET 130 in a conducting state for the duration of the second active period 175b of the second half cycle 174b. For keeping the high side NFET 130 in a conducting state for the duration of the second active period 175b of the second half cycle 174b, the bootstrap control unit 120 is arranged to couple the voltage in the bootstrap capacitor 125 in series to the voltage of the output node 155. The high side NFET 130 is kept in a conducting state with the voltage supplied by the high side control node 106. Thus, bootstrap control unit 120 is a version of a control unit 121. Bootstrap control unit 120 is arranged to be connected to a bootstrap capacitor 125 and with the voltage stored in the bootstrap capacitor 125, bootstrap control unit 120 is arranged to set an input voltage 106i to the high side control node 106 for setting the high side NFET 130 in a conducting state for the duration of the second active period 175b of the second half cycle 174b. Charging of the bootstrap capacitor 125 occurs during the first half cycle 174a. Bootstrap capacitor 125 and bootstrap control unit 120 are not shown in FIG. 6, however.

Referring back to FIG. 5 illustrating an embodiment comprising a current controlled current source 142, in an embodiment, the regulator 140 comprises a discharge diode 164 comprising a cathode node 164c and anode node 164a connected parallel to the regulating resistor 141 of FIG. 5, a cathode node 164c connected to the gate voltage input node 140i and an anode node 164a connected to the gate voltage output node 140o. The discharge diode 165 is not shown in FIG. 5, however.

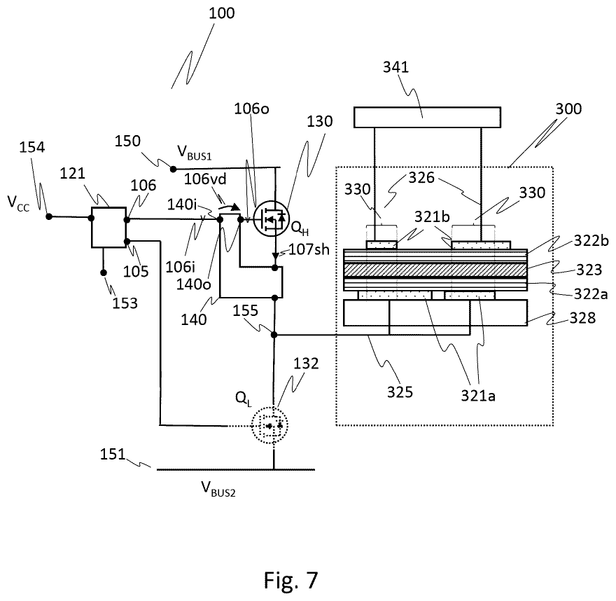

Referring to FIG. 7, according to another aspect of the present invention, an arrangement for driving a thin film electroluminescent TFEL display panel 300 with an NFET half bridge circuit 100 is shown. The TFEL display panel 300 comprises a display electrode which can be specifically a common display electrode 321a or a segment display electrode 321b. The TFET half bridge circuit 100 comprises a supply voltage node 154, a first bus voltage node 150 comprising a first bus voltage, a second bus voltage node 151 comprising a second bus voltage, and an output node 155 connected to the display electrode 321a, 321b of the TFEL display panel 300 for driving the TFEL display panel 300. The NFET half bridge circuit 100 is arranged to connect the output node 155 to the second bus voltage node 151 for the duration of a first active period 175a of a first half cycle 174a, and connect the output node 155 to the first bus voltage node 150 for the duration of a second active period 175b of a second half cycle 174b.

The NFET half bridge circuit 100 further comprises a high side NFET 130 element comprising a high gate node 130g, a high drain node 130d which is connected to the first bus voltage node 150, and a high source node 130s, and a low side NFET 132 element comprising a low gate node 132g, a low drain node 132d connected to the output node 155 and a low source node 132s connected to the second bus voltage node 151. The NFET half bridge circuit 100 further comprises a control unit 120, 121 comprising a low side control node 105 connected to the low gate node 132g of the low side NFET 132 and arranged to control the low side NFET 132 to a conducting state for the duration of the first active period 175a of the first half cycle 174a, and a high side control node 106 arranged to control the switching of the high side NFET 130, the high side control node 106 comprising an input voltage 106i for setting the high side NFET 130 in a conducting state for the duration of the second active period 175b of the second half cycle 174b. The NFET half bridge circuit 100 comprises further a regulator 140 arranged to determine a limited current 107sh from the high source node 130s of the high side NFET 130 and pass the limited current 107sh to the output node 155, connect the input voltage 106i of the high side control node 106 to the regulator 140, drop the input voltage 106i to the regulated voltage 106o by the voltage drop 106vd, which is directly governed by the limited current 107sh from the high source node 130s of the high side NFET 130, and connect the regulated voltage 106o to the high gate node 130g of the high side NFET 130.

Referring to still FIG. 7, according to an embodiment of the arrangement for driving a TFEL display panel 300, the NFET half bridge circuit 100 is an NFET half bridge circuit 100 as defined in the present application.

As shown in FIG. 7, the output node 155 may be connected with one or more conductors 325 to one or more common electrodes 321a of TFEL display panel 300. One or more segment electrodes 321b may be driven with their own driving electronics unit 341, connected to the one or more segment electrodes with one or more conductors 326. The TFEL display panel 300 comprises also insulating layers 322a and 322b, and between them, a phosphor layer 323 that emits light from an overlapping area 330 of a segment electrode and a common electrode, when an excitation voltage is applied to the segment and to the common electrode, excitation voltage being the voltage between the segment electrode and the common electrode. In other words, light emission occurs from the area of lateral overlap or overlapping area 330 of the segment and common electrodes. TFEL display panel 300 comprises also a substrate 328 on top of which the electrodes 321a and 321b, the insulating layers 322a and 322b and the phosphor layer 232 may be deposited e.g. by sputtering or atomic layer deposition methods, and electrodes 321a and 312b may be patterned e.g. by lithographical methods.

Alternatively, the output node 155 may be connected with one or more conductors to one or more segment electrodes 32 1b of TFEL display panel 300, and in this case, one or more common electrodes 321a may be driven with their own driving electronics unit 341 (this alternate arrangement is not shown in FIG. 7).

Still referring to FIG. 7, according to another aspect of the present invention, a use for driving a TFEL display panel 300 is disclosed. According to this aspect, an NFET half bridge circuit 100 as defined in the present application is used for driving a display electrode 321a, 321b of a TFEL display panel 300. Using an NFET half bridge circuit 100 as defined above for driving a display electrode 321a, 321b is described in detail by arrangement related aspect of the present application above.

It is evident for a skilled person that all circuit nodes of the NFET half bridge circuit 100 or 100′ in FIGS. 1-7 are arranged with bias voltages that arrange the NFET half bridge circuit 100 to operate as indicated in the present application. It is also evident for a skilled person that control electronics and powering electronics are connected to the NFET half bridge circuit 100 to enable its operation as part of a larger system. In the arrangement for driving a TFEL display panel 300, it is evident for a skilled person that other units like interfacing unit related to the displayed information and power supply unit related to required different voltage levels supplying required power for operation can be arranged by ways well known in the art. Similarly in the use of an NFET half bridge circuit 100 driving a display electrode of a TFEL display panel, it is evident for a skilled person that other units like interfacing unit related to the displayed information and power supply unit related to required different voltage levels can be arranged by ways well known in the art.

The invention has been described above with reference to the examples shown in the figures. However, the invention is in no way restricted to the above examples but may vary within the scope of the claims.

1. An N type Field-Effect Transistor (“NFET”) half bridge circuit comprising:
a supply voltage node,
a first bus voltage node comprising a first bus voltage,
a second bus voltage node comprising a second bus voltage,
an output node;
the NFET half bridge circuit being arranged to:
connect the output node to the second bus voltage node for the duration of a first active period of a first half cycle, and
connect the output node to the first bus voltage node for the duration of a second active period of a second half cycle;
the NFET half bridge circuit further comprising:
a high side NFET (130) element comprising a high gate node, a high drain node connected to the first bus voltage node, and a high source node,
a low side NFET element comprising a low gate node, a low drain node connected to the output node, and a low source node connected to the second bus voltage node,
a control unit comprising:
a low side control node connected to the low gate node of the low side NFET and arranged to control the low side NFET to a conducting state for the duration of the first active period of the first half cycle, and
a high side control node arranged to control the switching of the high side NFET, the high side control node comprising an input voltage for setting the high side NFET in a conducting state for the duration of the second active period of the second half cycle;
wherein the NFET half bridge circuit comprises a regulator arranged to:
determine a limited current from the high source node of the high side NFET and pass the limited current to the output node,
connect the input voltage of the high side control node to the regulator,
drop the input voltage to a regulated voltage by a voltage drop, which is directly governed by the limited current from the high source node of the high side NFET, and
connect the regulated voltage to the high gate node of the high side NFET.

2. An NFET half bridge circuit according to claim 1, wherein the regulator comprises:
a gate voltage input node connected to the high side control node, the gate voltage input node comprising the input voltage
a gate voltage output node connected to the high side NFET high gate node, the gate voltage output node comprising the regulated voltage,
a limited current input node connected to the high source node of the high side NFET,
a limited current output node connected to the output node;
and in that the regulator is arranged to:
drop the input voltage to the regulated voltage by the voltage drop, which is directly governed by the current between the limited current input node and the limited current output node of the regulator and
connect the regulated voltage to the gate voltage output node.

3. An NFET half bridge circuit according to claim 2, wherein the regulator comprises:
a regulating resistor connected between the gate voltage input node and the gate voltage output node, and
a current controlled current source comprising:
a controlling current input node connected to the limited current input node,
a controlling current output node connected to the limited current output node,
a controlled current input node connected to the gate voltage output node,
a controlled current output node connected to the limited current output node;
the current controlled current source being arranged to control the current between the controlled current input node and controlled current output node directly by the current flowing between the controlling current input node and the controlling current output node, current between the controlled current input node and controlled current output node causing the voltage drop over the regulating resistor from the input voltage to the regulated voltage.

4. An NFET half bridge circuit according to claim 2, wherein the regulator comprises:
a gate voltage output node connected to the high gate node of the high side NFET to connect the regulated voltage to the high gate node of the high side NFET element,
a regulating resistor connected between the gate voltage input node and the gate voltage output node,
an NPN type BJT comprising:
a base connected to the limited current input node,
an emitter connected to the limited current output node, and a collector connected to the gate voltage output node;
a base-emitter resistor connected between the limited current output node and the limited current input node, the base-emitter resistor arranged to regulate the NPN type BJT collector current based on the base-emitter voltage over the base-emitter resistor, collector current causing the voltage drop over the regulating resistor from the input voltage to the regulated voltage.

5. An NFET half bridge circuit according to claim 3, wherein the regulator comprises:
a discharge diode comprising a cathode node and an anode node connected parallel to the regulating resistor, cathode node connected to the gate voltage input node and anode node connected to the gate voltage output node.

6. An NFET half bridge circuit according to claim 1 wherein the control unit is a bootstrap control unit, and in that the NFET half bridge circuit comprises a bootstrap capacitor comprising a bootstrap capacitor first node and a bootstrap capacitor second node, the bootstrap capacitor first node being connected to the supply voltage node and the second node being connected to the output node, bootstrap control unit arranged to set the input voltage to the high side control node for setting the high side NFET in the conducting state for the duration of the second active period of the second half cycle with the voltage stored in the bootstrap capacitor.

7. An arrangement for driving a thin film electroluminescent (“TFEL”) display panel comprising a display electrode with an N type Field-Effect Transistor (“NFET”) half bridge circuit, wherein the NFET half bridge circuit comprises:
a supply voltage node,
a first bus voltage node comprising a first bus voltage,
a second bus voltage node comprising a second bus voltage,
an output node connected to the display electrode of the TFEL display panel for driving the TFEL display panel the NFET half bridge circuit being arranged to:
connect the output node to the second bus voltage node for the duration of a first active period of a first half cycle, and
connect the output node to the first bus voltage node for the duration of a second active period of a second half cycle;
the NFET half bridge circuit further comprising:
a high side NFET element comprising a high gate node (130g), a high drain node connected to the first bus voltage node, and a high source node,
a low side NFET element comprising a low gate node, a low drain node connected to the output node and a low source node connected to the second bus voltage node, a control unit comprising:
a low side control node connected to the low gate node of the low side NFET and arranged to control the low side NFET to a conducting state for the duration of the first active period of the first half cycle, and
a high side control node arranged to control the switching of the high side NFET, the high side control node comprising an input voltage for setting the high side NFET in a conducting state for the duration of the second active period of the second half cycle;
the NFET half bridge circuit further comprising a regulator arranged to:
determine a limited current from the high source node of the high side NFET and pass the limited current to the output node,
connect the input voltage of the high side control node to the regulator
drop the input voltage to a regulated voltage by a voltage drop, which is directly governed by the limited current from the high source node of the high side NFET, and
connect the regulated voltage to the high gate node of the high side NFET.

8. An arrangement according to claim 7, wherein the NFET half bridge circuit is an NFET half bridge circuit according to claim 1.

9. Use of an NFET half bridge circuit according to claim 1 for driving a display electrode of a TFEL display panel.
